(19) United States
(12) Patent Application Publication
(10) Pub. No.: US 2023/0008651 A1
(43) Pub. Date: Jan. 12, 2023

(54) JITTER DETERMINATION METHOD AND MEASUREMENT INSTRUMENT

(71) Applicant: Rohde & Schwarz GmbH & Co. KG, Munich (DE)

(72) Inventor: Andreas Maier, Munich (DE)

(73) Assignee: Rohde & Schwarz GmbH & Co. KG, Munich (DE)

(21) Appl. No.: 17/369,371

(22) Filed: Jul. 7, 2021

(51) Int. Cl. H04L 1/20; G01R 31/317; G01R 29/26

(52) U.S. Cl. CPC H04L 1/205; G01R 31/31709; G01R 29/26

(57) ABSTRACT

A jitter determination method for determining at least one jitter component of an input signal is described. The input signal is generated by a signal source. The jitter determination method includes: receiving the input signal; determining a step response based on the input signal, the step response being associated with at least the signal source; and determining at least one variation parameter associated with the determined step response, wherein the at least one variation parameter is indicative of a reliability of the determined step response. Further, a measurement instrument is described.

### FIELD OF THE DISCLOSURE

Embodiments of the present disclosure generally relate to a jitter determination method for determining at least one jitter component of an input signal. Embodiments of the present disclosure further relate to a measurement instrument.

### BACKGROUND

For jitter analysis, the components of jitter such as Data Dependent Jitter (DDJ), Periodic Jitter (PJ), Other Bounded Uncorrelated Jitter (OBUJ) and Random Jitter (RJ) must be separated and the bit error rate (BER) must be calculated.

So far, many known techniques exclusively relate to determining the Time Interval Error (TIE) of the Total Jitter (TJ). In some embodiments, the causes of the different jitter types lead to a distortion of the received signal and they, therefore, have an influence on the TIE via the received signal. Accordingly, the respective components of jitter are calculated once the Time Interval Error (TIE) of the Total Jitter (TJ) is determined.

However, it turned out that the measurement time is long if a high accuracy is to be achieved. Put another way, the signal length of the signal to be analyzed is long resulting in a long measuring duration if high precision is aimed for.

Moreover, the respective components of jitter are obtained by averaging operations. For instance, the Data Dependent Jitter (DDJ) is estimated by averaging the Time Interval Error (TIE) of the Total Jitter (TJ), namely e DDJ eye diagram or the DDJ worst case eye diagram. Moreover, certain components of jitter cannot be determined in a reliable manner.

New jitter determination techniques and measurement instruments have been developed that relate to determining a step response, and determining jitter components based on the determined step response.

Such a technique is, for example, described in US patent application US 2020 0 235 829 A1, which is incorporated herein by reference in its entirety.

There is a desire to further improve the reliability of the methods and measurement instruments described above.

### SUMMARY

Embodiments of the present disclosure provide a jitter determination method for determining at least one jitter component of an input signal, wherein the input signal is generated by a signal source. In an embodiment, the jitter determination method comprises the following steps:

receiving the input signal;

determining a step response based on the input signal, the step response being associated with at least the signal source; and

determining at least one variation parameter associated with the determined step response, wherein the at least one variation parameter is indicative of a reliability of the determined step response.

In general, the term “determining a step response” is understood to denote that a plurality of samples associated with the step response is determined.

The at least one variation parameter may be determined for the step response as a whole and/or for the individual samples associated with the step response, respectively.

The jitter determination method according to principles of the present disclosure is based on the idea to provide additional information regarding the reliability of the determined step response, namely the at least one variation parameter.

In general, the at least one variation parameter comprises additional information on the variation of the determined step response, more precisely on the variation of samples associated with the determined step response.

Thus, additional information on the determined step response is provided that can help a user in assessing the reliability of the determined step response.

For example, if the at least one variation parameter indicates a large variation of the samples associated with the determined step response, it may be concluded that there is an error and/or perturbation in the measurement setup that prevents a precise calculation of the step response.

If, on the other hand, the at least one variation parameter indicates a small variation of the samples associated with the determined step response, it may be concluded that the determined step response is trustworthy.

Thus, the at least one variation parameter provides an easy to understand measure for the reliability of the determined step response. Accordingly, even inexperienced users can assess whether the determined step response is correct without knowledge of the supposed shape of the step response.

According to an aspect of the present disclosure, the at least one variation parameter comprises at least one of a confidence interval, a standard deviation, a variance, a range, or a span.

The confidence interval represents an interval in which the true value of the step response or rather the true values of the respective samples associated with the step response lie with a probability of 95%. Thus, the confidence interval is a statistic measure that is particularly easy to understand even for inexperienced users.

The standard deviation and the variance are well-known and easy to understand measures for the variation of the step response or of the individual samples associated with the step response.

The range corresponds to the difference of the maximum value and the minimum value of the respective sample(s) associated with the step response. Accordingly, the range is an easy to understand measure for the overall variation of the step response.

The span corresponds to the difference between the 95^{th} percentile and the 5^{th} percentile of the respective sample(s) associated with the step response. Thus, the span is an easy to understand measure for the overall variation of the step response. However, the span is less susceptible to extreme outliers compared to the range.

According to another aspect of the present disclosure, the step response is determined by a least squares technique. In some embodiments, a cost functional may be provided, wherein the cost functional may depend on the step response to be determined or rather on the individual samples of the step response to be determined. The cost functional may be minimized by the least squares technique, thereby obtaining the step response.

In an embodiment of the present disclosure, a covariance matrix or a covariance submatrix associated with the step response is determined at least partially, wherein the at least one variation parameter is determined based on the determined covariance matrix or the determined covariance submatrix. The covariance matrix comprises information on the variation of the individual samples associated with the step response. The covariance matrix may further comprise information on correlations between the individual samples.

The covariance matrix may be simplified by applying at least one of the following approximations.

The individual samples may be assumed to each have the same variance σ_{yy}² Thus, the overall number of variation parameters to be determined is reduced, as the respective variation parameter for each sample associated with the step response is the same.

The individual samples associated with the step response may be assumed to be uncorrelated. Thus, the covariance matrix becomes a diagonal matrix, as all off-diagonal elements describing the cross-correlations are zero.

In a further embodiment of the present disclosure, the at least one variation parameter is determined based on a diagonal of the determined covariance matrix or a diagonal of the determined covariance submatrix. In general, the diagonal of the covariance matrix is associated with the variances of the respective samples, while off-diagonal elements of the covariance matrix are associated with correlations between different samples. Thus, the at least one variation parameter can be determined based on the diagonal elements of the covariance matrix or of the covariance submatrix.

According to a further aspect of the present disclosure, the step response and at least one periodic perturbation component of the input signal are determined jointly. In other words, the step response and the at least one periodic perturbation component are determined simultaneously instead of consecutively. In general, the accuracy of a joint determination of several parameters is better than the consecutive determination of these parameters. Thus, the accuracy of the determined step response and the at least one determined periodic perturbation component is enhanced by the joint determination.

The at least one periodic perturbation component may comprise for example at least one of periodic jitter or periodic noise.

In some embodiments, the at least one periodic perturbation component is a vertical periodic perturbation component. Accordingly, the periodic perturbation, i.e. the periodic jitter and/or periodic noise, may be caused by “vertical” amplitude perturbations.

In an embodiment of the present disclosure, a rough estimate of the at least one periodic perturbation component is determined, wherein the step response and the at least one periodic perturbation component of the input signal are determined jointly based on the rough estimate of the at least one periodic perturbation component. In some embodiments, approximate values of signal parameters associated with the at least one periodic perturbation may be roughly estimated initially. The true values of the respective periodic perturbations may deviate from these roughly estimated values.

In some embodiments, the at least one periodic perturbation component may be determined based on a mathematical substitute model of the input signal. The substitute model of the input signal may comprise parameters for the least one perturbation component to be determined, for example for several jitter and/or noise components to be determined. By fitting the substitute model parameters to the input signal, the substitute model parameters and thus the at least one periodic perturbation component can be determined. The substitute model parameters may be fitted to the input signal via a suitable stochastic method, for example via a regression analysis.

The substitute model may be linearized with respect to the deviations of the true values of the respective periodic perturbations from the corresponding roughly estimated values. In other words, the substitute model may be Taylor-expanded in the deviations around the roughly estimated signal parameter values.

According to an aspect of the present disclosure, a graphic representation of the at least one variation parameter is determined. In general, the graphic representation may comprise at least one of a diagram, a text message, an icon, a two-dimensional plot, a three-dimensional plot, or a heat map.

Additionally or alternatively, the graphic representation may comprise a predefined coloring corresponding to predefined quantities, such that the different quantities are easily distinguishable. For example, a different color may be associated with the determined step response compared to the at least one determined variation parameter.

According to another aspect of the present disclosure, the graphic representation is visualized on a display. In some embodiments, the graphic representation may be visualized on a display of a measurement instrument and/or on an external display. Thus, the information regarding the at least one variation parameter is presented in an intuitive way, as the user does not have to manually evaluate the numeric result(s) for the at least one determined variation parameter.

In some embodiments, the graphic representation of the at least one variation parameter is visualized together with a graphic representation of the determined step response. For example, the determined step response may be visualized as a diagram, wherein values of the samples associated with the determined step response may be plotted against time. The at least one determined variation parameter may be visualized as an area around the plot of the determined step response. Alternatively or additionally, the at least one variation parameter may be visualized as an upper threshold function and/or as a lower threshold function indicating the at least one variation parameter with respect to the determined step response.

In an embodiment of the present disclosure, the graphic representation comprises a user warning if a value of the at least one variation parameter is greater than a predetermined threshold. In general, a large value of the at least one variation parameter may indicate that the determined step response is not particularly reliable, as the determined values of the samples (each) have a large variation. In other words, the user is automatically warned if the variation of the determined step response is larger than the predetermined threshold, which is an indication of a potentially not reliable result for the step response.

In a further embodiment of the present disclosure, the user warning comprises at least one of a coloring, a text message, or a warning sign. In general, the user warning may be configured such that the user attention is immediately drawn to the user warning. For example, the user warning may be display as an overlay to the graphic representation of the at least one variation parameter and/or the graphic representation of the determined step response. Alternatively or additionally, the user warning may have a distinctively different coloring than the graphic representation of the at least one variation parameter and/or the graphic representation of the determined step response.

According to an aspect of the present disclosure, the input signal is pulse amplitude modulation (PAM)-N coded, wherein N is an integer greater than 1. Accordingly, the method is not limited to binary signals (PAM-2 coded) since any kind of pulse-amplitude modulated signals may be processed.

According to further embodiment of the present disclosure, at least one jitter component of the input signal is determined based on the determined step response. Accordingly, one or more components of the total jitter are determined based on the input signal and based on the determined step response. In some embodiments, the one or more components of the total jitter are determined based on both the input signal and the determined step response. For example, at least one of data dependent jitter or periodic jitter is determined.

Embodiments of the present disclosure further provide a measurement instrument. In an embodiment, the measurement instrument comprises at least one input channel and an analysis circuit or module being connected to the at least one input channel. The measurement instrument is configured to receive an input signal via the at least one input channel and to forward the received input signal to the analysis module. The analysis module is configured to determine a step response based on the received input signal, wherein the step response is associated with at least a signal source generating the input signal. The analysis module further is configured to determine at least one variation parameter associated with the determined step response, wherein the at least one variation parameter is indicative of a reliability of the determined step response.

In some embodiments, the measurement instrument is configured to perform one or more of the jitter determination methods described above.

Regarding the advantages and further properties of the measurement instrument, reference is made to the explanations given above with respect to the jitter determination method, which also hold for the measurement instrument and vice versa.

According to an aspect of the present disclosure, the at least one variation parameter comprises at least one of a confidence interval, a standard deviation, a variance, a range, or a span.

The confidence interval represents an interval in which the true value of the step response or rather the true values of the respective samples associated with the step response lie with a probability of 95%. Thus, the confidence interval is a statistic measure that is particularly easy to understand even for inexperienced users.

The standard deviation and the variance are well-known and easy to understand measures for the variation of the step response or of the individual samples associated with the step response The range corresponds to the difference of the maximum value and the minimum value of the respective sample(s) associated with the step response. Accordingly, the range is an easy to understand measure for the overall variation of the step response.

The span corresponds to the difference between the 95^{th} percentile and the 5^{th} percentile of the respective sample(s) associated with the step response. Thus, the span is an easy to understand measure for the overall variation of the step response. However, the span is less susceptible to extreme outliers compared to the range.

According to another aspect of the present disclosure, the measurement instrument further comprises a display, wherein the measurement instrument is configured to visualize the at least one determined variation parameter on the display. Thus, the information regarding the at least one variation parameter is presented in an intuitive way, as the user does not have to manually evaluate the numeric result(s) for the at least one determined variation parameter.

In an embodiment of the present disclosure, the measurement instrument is configured to visualize the at least one determined variation parameter and the determined step response on the display simultaneously. For example, the determined step response may be visualized as a diagram, wherein values of the samples associated with the determined step response may be plotted against time. The at least one determined variation parameter may be visualized as an area around the plot of the determined step response. Alternatively or additionally, the at least one variation parameter may be visualized as an upper threshold function and/or as a lower threshold function indicating the at least one variation parameter with respect to the determined step response.

In a further embodiment of the present disclosure, the measurement instrument is an oscilloscope. Alternatively, the measurement instrument may be a spectrum analyzer, a signal analyzer or a vector network analyzer. Thus, an oscilloscope, a spectrum analyser, a signal analyser, and/or a vector network analyser may be provided that is enabled to perform the jitter determination methods described above for determining at least one jitter component of an input signal.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 schematically shows a measurement system with an example measurement instrument according to an embodiment of the present disclosure;

FIG. 2 shows a tree diagram of different types of jitter and different types of noise;

FIG. 3 shows a flow chart of a jitter determination method according to an embodiment of the present disclosure;

FIG. 4 shows a further flow chart of a jitter determination method according to an embodiment of the present disclosure; and

FIG. 5 shows a diagram of a step response and a variation parameter plotted against time.

### DETAILED DESCRIPTION

The detailed description set forth above in connection with the appended drawings, where like numerals reference like elements, are intended as a description of various embodiments of the present disclosure and are not intended to represent the only embodiments. Each embodiment described in this disclosure is provided merely as an example or illustration and should not be construed as preferred or advantageous over other embodiments. The illustrative examples provided herein are not intended to be exhaustive or to limit the disclosure to the precise forms disclosed. Similarly, any steps described herein may be interchangeable with other steps, or combinations of steps, in order to achieve the same or substantially similar result. Moreover, some of the method steps can be carried serially or in parallel, or in any order unless specifically expressed or understood in the context of other method steps.

In the foregoing description, specific details are set forth to provide a thorough understanding of exemplary embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure. Further, it will be appreciated that embodiments of the present disclosure may employ any combination of features described herein.

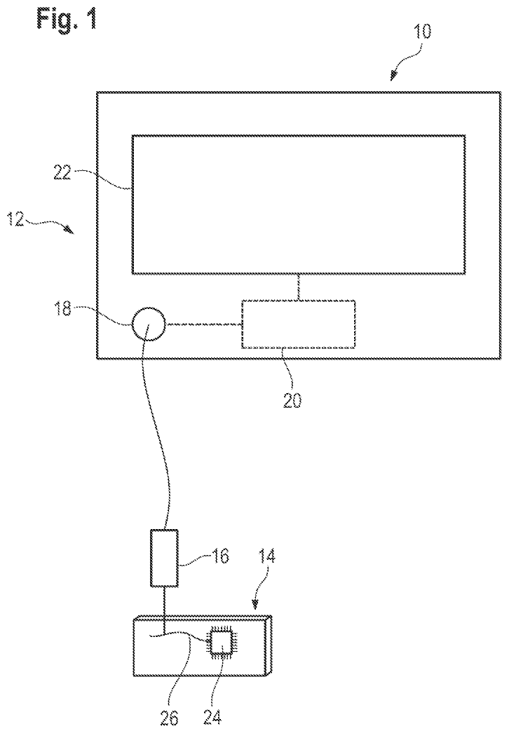

FIG. 1 schematically shows a measurement system 10 comprising a measurement instrument 12 and a device under test 14. The measurement instrument 12 comprises a probe 16, an input channel 18, an analysis circuit or module 20 and a display 22.

The probe 16 is connected to the input channel 18, which in turn is connected to the analysis module 20. The display 22 is connected to the analysis module 20 and/or to the input channel 18 directly. Typically, a housing is provided that encompasses at least the analysis module 20.

Generally, the measurement instrument 12 may be established as an oscilloscope, as a signal analyzer, as a spectrum analyzer, as a vector network analyzer or as any other kind of measurement device being configured to measure certain properties of the device under test 14.

The device under test 14 comprises a signal source 24 as well as a transmission channel 26 connected to the signal source 24. In general, the signal source 24 is configured to generate an electrical signal that propagates via the transmission channel 26. In some embodiments, the device under test 14 comprises a signal sink to which the signal generated by the signal source 24 propagates via the transmission channel 26.

More specifically, the signal source 24 generates the electrical signal that is then transmitted via the transmission channel 26 and probed by the probe 16, for example a tip of the probe 16. In some embodiments, the electrical signal generated by the signal source 24 is forwarded via the transmission channel 26 to a location where the probe 16, for example its tip, can contact the device under test 14 in order to measure the input signal.

Thus, the electrical signal may generally be sensed between the signal source 24 and the signal sink assigned to the signal source 24, wherein the electrical signal may also be probed at the signal source 24 or the signal sink directly. Put another way, the measurement instrument 12, for example the analysis module 20, receives an input signal via the probe 16 that senses the electrical signal.

The input signal probed is forwarded to the analysis module 20 via the input channel 18. The input signal is then processed and/or analyzed by the analysis module 20 in order to determine the properties of the device under test 14.

Therein and in the following, the term “input signal” is understood to be a collective term for all stages of the signal generated by the signal source 24 that exist before the signal reaches the analysis module 20. In other words, the input signal may be altered by the transmission channel 26 and/or by other components of the device under test 14 and/or of the measurement instrument 12 that process the input signal before it reaches the analysis module 20. Accordingly, the input signal relates to the signal that is received and analyzed by the analysis module 20.

The input signal usually contains perturbations in the form of total jitter (TJ) that is a perturbation in time and total noise (TN) that is a perturbation in amplitude. The total jitter and the total noise in turn each comprise several components. Note that the abbreviations introduced in parentheses will be used in the following.

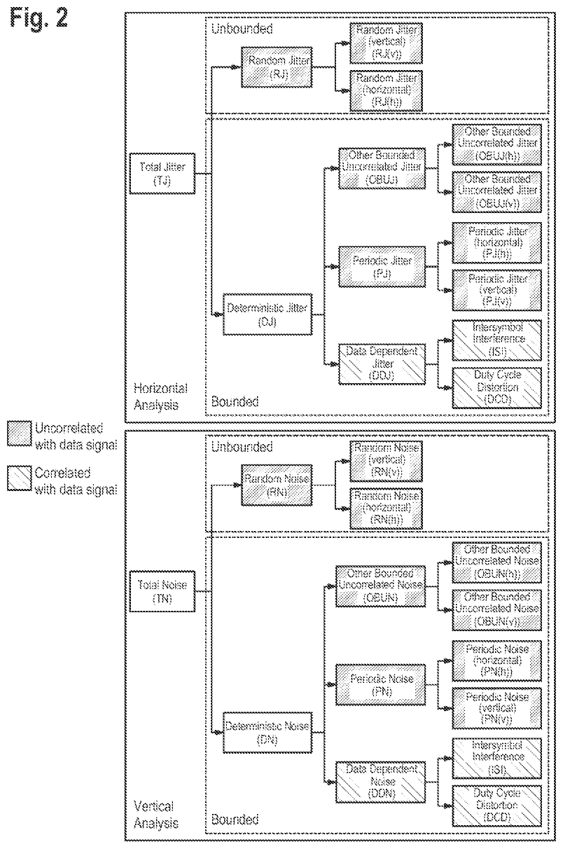

As is shown in FIG. 2, the total jitter (TJ) is composed of random jitter (RJ) and deterministic jitter (DJ), wherein the random jitter (RJ) is unbounded and randomly distributed, and wherein the deterministic jitter (DJ) is bounded.

The deterministic jitter (DJ) itself comprises data dependent jitter (DDJ), periodic jitter (PJ) and other bounded uncorrelated jitter (OBUJ).

The data dependent jitter is directly correlated with the input signal, for example directly correlated with signal edges in the input signal. The periodic jitter is uncorrelated with the input signal and comprises perturbations that are periodic, for example in time.

The other bounded uncorrelated jitter comprises all deterministic perturbations that are neither correlated with the input signal nor periodic. The data dependent jitter comprises up to two components, namely inter-symbol interference (ISI) and duty cycle distortion (DCD).

Analogously, the total noise (TN) comprises random noise (RN) and deterministic noise (DN), wherein the deterministic noise contains data dependent noise (DDN), periodic noise (PN) and other bounded uncorrelated noise (OBUN).

Similarly to the jitter, the data dependent noise is directly correlated with the input signal, for example directly correlated with signal edges in the input signal. The periodic noise is uncorrelated with the input signal and comprises perturbations that are periodic, for example in amplitude. The other bounded uncorrelated noise comprises all deterministic perturbations that are neither correlated with the input signal nor periodic. The data dependent noise comprises up to two components, namely inter-symbol interference (ISI) and duty cycle distortion (DCD).

In general, there is cross-talk between the perturbations in time and the perturbations in amplitude.

Put another way, jitter may be caused by “horizontal” temporal perturbations, which is denoted by “(h)” in FIG. 2 and in the following, and/or by “vertical” amplitude perturbations, which is denoted by a “(v)” in FIG. 2 and in the following.

Likewise, noise may be caused by “horizontal” temporal perturbations, which is denoted by “(h)” in FIG. 2 and in the following, and/or by “vertical” amplitude perturbations, which is denoted by a “(v)” in FIG. 2 and in the following.

In detail, the terminology used below is the following:

Horizontal periodic jitter PJ(h) is periodic jitter that is caused by a temporal perturbation.

Vertical periodic jitter PJ(ν) is periodic jitter that is caused by an amplitude perturbation.

Horizontal other bounded uncorrelated jitter OBUJ(h) is other bounded uncorrelated jitter that is caused by a temporal perturbation.

Vertical other bounded uncorrelated jitter OBUJ(ν) is other bounded uncorrelated jitter that is caused by an amplitude perturbation.

Horizontal random jitter RJ(h) is random jitter that is caused by a temporal perturbation.

Vertical random jitter RJ(ν) is random jitter that is caused by an amplitude perturbation.

The definitions for noise are analogous to those for jitter:

Horizontal periodic noise PN(h) is periodic noise that is caused by a temporal perturbation.

Vertical periodic noise PN(ν) is periodic noise that is caused by an amplitude perturbation.

Horizontal other bounded uncorrelated noise OBUN(h) is other bounded uncorrelated noise that is caused by a temporal perturbation.

Vertical other bounded uncorrelated noise OBUN(ν) is other bounded uncorrelated noise that is caused by an amplitude perturbation.

Horizontal random noise RN(h) is random noise that is caused by a temporal perturbation.

Vertical random noise RN(ν) is random noise that is caused by an amplitude perturbation.

As mentioned above, noise and jitter each may be caused by “horizontal” temporal perturbations and/or by “vertical” amplitude perturbations.

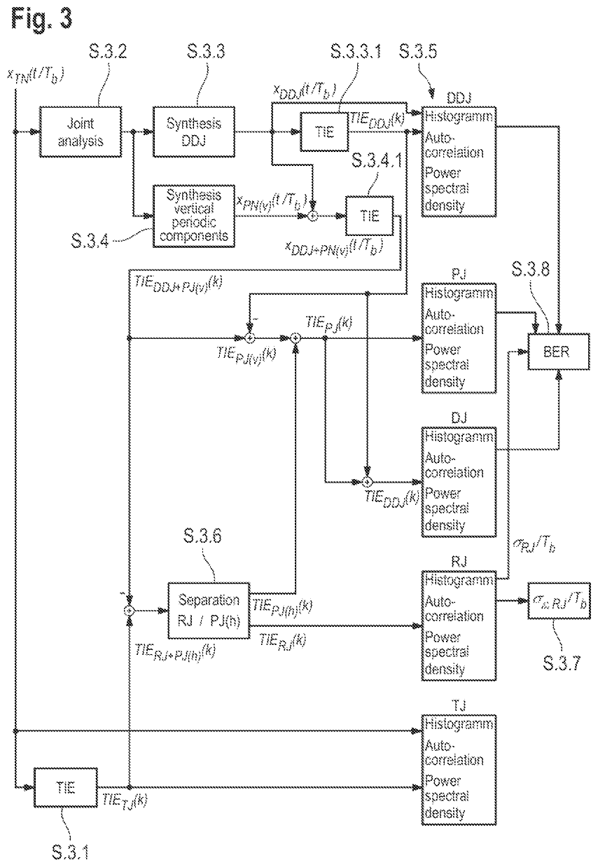

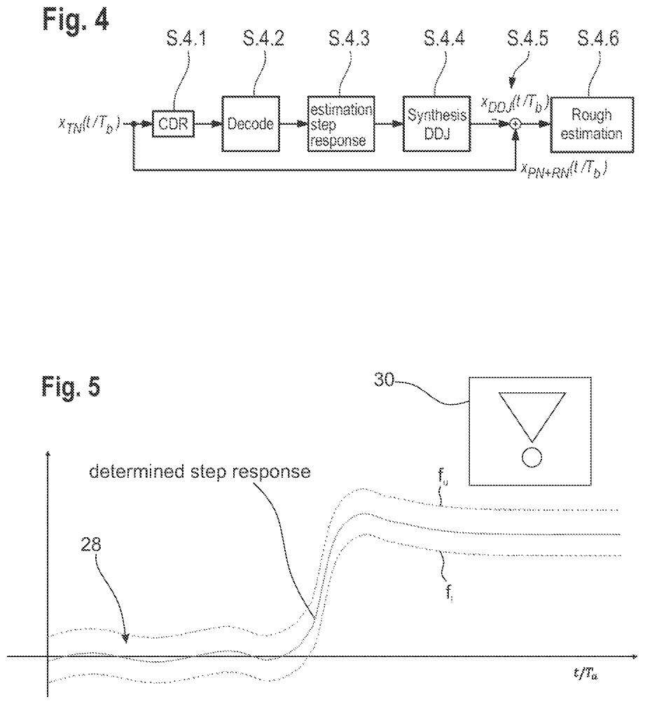

The measurement instrument 12 or rather the analysis module 20 is configured to perform the steps schematically shown in FIG. 3 and/or FIG. 4 in order to analyze the jitter and/or noise components contained within the input signal, namely the jitter and/or noise components mentioned above.

Model of the Input Signal

First of all, a mathematical substitute model of the input signal or rather of the jitter components and the noise components of the input signal is established. Without loss of generality, the input signal is assumed to be PAM-N coded in the following, wherein N is an integer bigger than 1. Hence, the input signal may be a binary signal (PAM-2 coded).

Based on the categorization explained above with reference to FIG. 2, the input signal at a time t/T_{b} is modelled as

$${x}_{TN} ( t / {T}_{b} ) = {\sum }_{k = - {N}_{pre}}^{{N}_{post}} b ( k ) \cdot h ( t / {T}_{b} - k - ε ( k ) / {T}_{b} ) + {\sum }_{i = 0}^{{N}_{PN ( v )} - 1} {A}_{i} \cdot sin ( 2 π \cdot {f}_{i} / {f}_{b} \cdot t / {T}_{b} + {ϕ}_{i} ) + {x}_{RN ( v )} ( t / {T}_{b} ) + {x}_{OBUN ( v )} ( t / {T}_{b} ) . \qquad ( E \text{.1} )$$

In the first term, namely

$${\sum }_{k = - {N}_{pre}}^{{N}_{post}} b ( k ) \cdot h ( t / {T}_{b} - k - ε ( k ) / {T}_{b} ) ,$$

b(k) represents a bit sequence sent by the signal source 24 via the transmission channel 26, wherein T_{b} is the bit period.

Note that strictly speaking the term “bit” is only correct for a PAM-2 coded input signal. However, the term “bit” is to be understood to also include a corresponding signal symbol of the PAM-n coded input signal for arbitrary integer n.

h(t/T_{b}) is the joint impulse response of the signal source 24 and the transmission channel 26. In case of directly probing the signal source 24, h(t/T_{b}) is the impulse response of the signal source 24 since no transmission channel 26 is provided or rather necessary.

Note that the joint impulse response h(t/T_{b}) does not comprise contributions that are caused by the probe 16, as these contributions are usually compensated by the measurement instrument 12 or the probe 16 itself in a process called “de-embedding”. Moreover, contributions from the probe 16 to the joint impulse response h(t/T_{b}) may be negligible compared to contributions from the signal source 24 and the transmission channel 26.

Nₚᵣₑ and Nₚₒₛₜ respectively represent the number of bits before and after the current bit that perturb the input signal due to inter-symbol interference. As already mentioned, the length Nₚᵣₑ+Nₚₒₛₜ+1 may comprise several bits, for example several hundred bits, especially in case of occurring reflections in the transmission channel 26.

Further, ε(k) is a function describing the time perturbation, i.e. ε(k) represents the temporal jitter.

Moreover, the input signal also contains periodic noise perturbations, which are represented by the second term in equation (E.1), namely

$${\sum }_{i = 0}^{{N}_{PN ( v )} - 1} {A}_{i} \cdot sin ( 2 π \cdot {f}_{i} / {f}_{b} \cdot t / {T}_{b} + {ϕ}_{i} ) .$$

The periodic noise perturbation is modelled by a series over N_{PN(ν)} sine-functions with respective amplitudes Aᵢ, frequencies ƒᵢ and phases ϕᵢ, which is equivalent to a Fourier series of the vertical periodic noise.

The last two terms in equation (E.1), namely

+x_{RN(ν)}(t/T_{b})+x_{OBUN(ν)}(t/T_{b}),

represent the vertical random noise and the vertical other bounded uncorrelated noise contained in the input signal, respectively.

The function ε(k) describing the temporal jitter is modelled as follows:

$$ε ( k ) / {T}_{b} = {\sum }_{i = 0}^{{N}_{PJ ( h )} - 1} {a}_{i} / {T}_{b} \cdot sin ( 2 π \cdot {ϑ}_{i} / {f}_{b} \cdot k + {φ}_{i} ) + {ε}_{RJ} ( k ) / {T}_{b} + {ε}_{OBUJ} ( k ) / {T}_{b} . \qquad ( E \text{.2} )$$

The first term in equation (E.2), namely

$${\sum }_{i = 0}^{{N}_{PJ ( h )} - 1} {a}_{i} / {T}_{b} \cdot sin ( 2 π \cdot {ϑ}_{i} / {f}_{b} \cdot k + {φ}_{i} ) ,$$

represents the periodic jitter components that are modelled by a series over N_{PJ(h)} sine-functions with respective amplitudes aᵢ, frequencies ϑᵢ and phases φᵢ, which is equivalent to a Fourier series of the horizontal periodic jitter.

The last two terms in equation (E.2), namely

ε_{RJ}(k)/T_{b}+εOBUJ(k)/T_{b},

represent the random jitter and the other bounded uncorrelated jitter contained in the total jitter, respectively.

In order to model duty cycle distortion (DCD), the model of (E.1) has to be adapted to depend on the joint step response hₛ(t/T_{b},b(k)) of the signal source 24 and the transmission channel 26.

As mentioned earlier, the step response hₛ(t/T_{b},b(k)) of the signal source 24 may be taken into account provided that the input signal is probed at the signal source 24 directly.

Generally, duty cycle distortion (DCD) occurs when the step response for a rising edge signal is different to the one for a falling edge signal.

The inter-symbol interference relates, for example, to limited transmission channel or rather reflection in the transmission.

The adapted model of the input signal due to the respective step response is given by

$${x}_{TN} ( t / {T}_{b} ) = {\sum }_{k = - {N}_{pre}}^{{N}_{post}} [ b ( k ) - b ( k - 1 ) ] \cdot {h}_{s} ( t / {T}_{b} - k - ε ( k ) / {T}_{b} , b ( k ) ) + {x}_{- ∞} + {\sum }_{i = 0}^{{N}_{PN} ( v ) - 1} {A}_{i} \cdot sin ( 2 π \cdot {f}_{i} / {f}_{b} \cdot t / {T}_{b} + {ϕ}_{i} ) + {x}_{RN ( v )} ( t / {T}_{b} ) + {x}_{OBUN ( v )} ( t / {T}_{b} ) . \qquad ( E \text{.3} )$$

Therein, x_{-∞}, represents the state at the start of the transmission of the input signal, for example the state of the signal source 24 and the transmission channel 26 at the start of the transmission of the input signal.

The step response hₛ(t/T_{b},b(k)) depends on the bit sequence b(k), or more precisely on a sequence of N_{DCD} bits of the bit sequence b(k), wherein N_{DCD} is an integer bigger than 1.

Note that there is an alternative formulation of the duty cycle distortion that employs N_{DCD}=1. This formulation, however, is a mere mathematical reformulation of the same problem and thus equivalent to the present disclosure.

Accordingly, the step response hₛ(t/T_{b},b(k)) may generally depend on a sequence of N_{DCD} bits of the bit sequence b(k), wherein N_{DCD} is an integer value.

Typically, the dependency of the step response hₛ(t/T_{b},b(k)) on the bit sequence b(k) ranges only over a few bits, for instance N_{DCD}=2, 3, . . . , 6.

For N_{DCD}=2 this is known as “double edge response (DER)”, while for N_{DCD}>2 this is known as “multi edge response (MER)”.

Without restriction of generality, the case N_{DCD}=2 is described in the following. However, the outlined steps also apply to the case N_{DCD}>2 with the appropriate changes. As indicated above, the following may also be (mathematically) reformulated for N_{DCD}=1.

In equation (E.3), the term b(k)−b(k−1), which is multiplied with the step response hₛ(t/T_{b},b(k)), takes two subsequent bit sequences, namely b(k) and b(k−1), into account such that a certain signal edge is encompassed.

In general, there may be two different values for the step response hₛ(t/T_{b},b(k)), namely hₛ^{(r)}(t/T_{b}) for a rising signal edge and hₛ^{(ƒ)}(t/T_{b}) for a falling signal edge. In other words, the step response hₛ(t/T_{b},b(k)) may take the following two values:

$${h}_{s} ( t / {T}_{b} , b ( k ) ) = \{ \begin{matrix}{h}_{s}^{( r )} ( t / {T}_{b} ) , & b ( k ) - b ( k - 1 ) \geq 0 \\ {h}_{s}^{( f )} ( t / {T}_{b} ) , & b ( k ) - b ( k - 1 ) < 0.\end{matrix} \qquad ( E \text{.4} )$$

If the temporal jitter ε(k) is small, equation (E.3) can be linearized and then becomes

$${x}_{TN} ( t / {T}_{b} ) \approx {\sum }_{k = - {N}_{pre}}^{{N}_{post}} [ b ( k ) - b ( k - 1 ) ] \cdot {h}_{s} ( t / {T}_{b} - k , b ( k ) ) + {x}_{- ∞} + {\sum }_{i = 0}^{{N}_{PN ( v )} - 1} {A}_{i} \cdot sin ( 2 π \cdot {f}_{i} / {f}_{b} \cdot t / {T}_{b} + {ϕ}_{i} ) + {x}_{RN ( v )} ( t / {T}_{b} ) + {x}_{OBUN ( v )} ( t / {T}_{b} ) - {\sum }_{k = - {N}_{pre}}^{{N}_{post}} ε ( k ) / {T}_{b} \cdot [ b ( k ) - b ( k - 1 ) ] \cdot h ( t / {T}_{b} - k , b ( k ) ) . \qquad ( E \text{.5} )$$

Note that the last term in equation (E.5), namely

$${\sum }_{k = - {N}_{pre}}^{{N}_{post}} ε ( k ) / {T}_{b} \cdot [ b ( k ) - b ( k - 1 ) ] \cdot h ( t / {T}_{b} - k , b ( k ) ) ,$$

describes an amplitude perturbation that is caused by the temporal jitter ε(k).

It is to be noted that the input signal comprises the total jitter as well as the total noise so that the input signal may also be labelled by x_{TJ}(t/T_{b}).

Clock Data Recovery A clock data recovery is performed based on the received input signal employing a clock timing model of the input signal, which clock timing model is a slightly modified version of the substitute model explained above. The clock timing model will be explained in more detail below.

Generally, the clock signal T_{clk} is determined while simultaneously determining the bit period T_{b} from the times t_{edge}(i) of signal edges based on the received input signal.

More precisely, the bit period T_{b} scaled by the sampling rate 1/Tₐ is inter alia determined by the analysis module 20.

In the following, \hat{T}_{b}/Tₐ is understood to be the bit period that is determined by the analysis module 20. The symbol “\hat{ }” marks quantities that are determined by the analysis module 20, for example quantities that are estimated by the analysis module 20.

One aim of the clock data recovery is to also determine a time interval error TIE (k) caused by the different types of perturbations explained above.

Moreover, the clock data recovery may also be used for decoding the input signal, for determining the step response h(t/T_{b}) and/or for reconstructing the input signal. Each of these applications will be explained in more detail below.

Note that for each of these applications, the same clock data recovery may be performed. Alternatively, a different type of clock data recovery may be performed for at least one of these applications.

In order to enhance the precision or rather accuracy of the clock data recovery, the bit period \hat{T}_{b}/Tₐ is determined jointly with at least one of the deterministic jitter components mentioned above and with a deviation Δ\hat{T}_{b}/Tₐ from the bit period \hat{T}_{b}/Tₐ.

In the case described in the following, the bit period \hat{T}_{b}/Tₐ and the deviation Δ\hat{T}_{b}/Tₐ are estimated together with the data dependent jitter component and the periodic jitter components. Therefore, the respective jitter components are taken into account when providing a cost functional that is to be minimized.

The principle of minimizing a cost functional, also called criterion, in order to determine the clock signal T_{clk} is known.

In some embodiments, the bit period \hat{T}_{b}/Tₐ and the deviation Δ\hat{T}_{b}/Tₐ are determined by determining the times t_{edge}(i) of signal edges based on the received input signal and by then minimizing the following cost functional K, for example by employing a least mean squares approach:

$$\begin{matrix}K = {\sum }_{i = 0}^{N - 1} [ \frac{{t}_{edge} ( i )}{{T}_{a}} - {k}_{i , η} \cdot \frac{{\hat{T}}_{b} ( η )}{{T}_{a}} - \frac{Δ {\hat{T}}_{b} ( η )}{{T}_{a}} - \\ {\sum }_{{L}_{{ISI}_{pre}}}^{{L}_{{ISI}_{post}}} {\hat{h}}_{r , f} ( {k}_{i} - ξ , b ( {k}_{i} ) , b ( {k}_{i} - 1 ) , b ( {k}_{i} - ξ ) , b ( {k}_{i} - ξ - 1 ) ) - \\ {{\sum }_{μ = 0}^{{M}_{PJ} - 1} {\hat{C}}_{μ} \cdot sin ( 2 π \cdot {\hat{v}}_{μ} / {T}_{a} \cdot {k}_{i} + {Ψ}_{μ} ) ]}^{2} .\end{matrix} \qquad ( E \text{.6} )$$

As mentioned above, the cost functional K used by the method according to the present disclosure comprises terms concerning the data dependent jitter component, which is represented by the fourth term in equation (E.6) and the periodic jitter components, which are represented by the fifth term in equation (E.6), namely the vertical periodic jitter components and/or the horizontal periodic jitter components.

Therein, L_{ISI}, namely the length L_{ISI}_{ₚᵣₑ}+L_{ISI}_{ₚₒₛₜ}, is the length of an Inter-symbol Interference filter (ISI-filter) ĥ_{r,ƒ}(k) that is known from the state of the art and that is used to model the data dependent jitter. The length L_{ISI} should be chosen to be equal or longer than the length of the impulse response, namely the one of the signal source 24 and the transmission channel 26.

Hence, the cost functional K takes several signal perturbations into account rather than assigning their influences to (random) distortions as typically done in the prior art.

In some embodiments, the term

$${\sum }_{{L}_{{ISI}_{pre}}}^{{L}_{{ISI}_{post}}} {\hat{h}}_{r , f} ( {k}_{i} - ξ , b ( {k}_{i} ) , b ( {k}_{i} - 1 ) , b ( {k}_{i} - ξ ) , b ( {k}_{i} - ξ - 1 ) )$$

relates to the data dependent jitter component. The term assigned to the data dependent jitter component has several arguments for improving the accuracy since neighbored edge signals, also called aggressors, are taken into account that influence the edge signal under investigation, also called victim.

In addition, the term

$${\sum }_{μ = 0}^{{M}_{PJ} - 1} {\hat{C}}_{μ} \cdot sin ( 2 π \cdot {\hat{v}}_{μ} / {T}_{a} \cdot {k}_{i} + {\hat{Ψ}}_{μ} )$$

concerns the periodic jitter components, namely the vertical periodic jitter components and/or the horizontal periodic jitter components, that are also explicitly mentioned as described above. Put it another way, it is assumed that periodic perturbations occur in the received input signal which are taken into consideration appropriately.

If the signal source 24 is configured to perform spread spectrum clocking, then the bit period T_{b}/Tₐ is not constant but varies over time.

The bit period can then, as shown above, be written as a constant central bit period T_{b}, namely a central bit period being constant in time, plus a deviation ΔT_{b} from the central bit period T_{b}, wherein the deviation ΔT_{b} varies over time.

In this case, the period of observation is divided into several time slices or rather time sub-ranges. For ensuring the above concept, the several time slices are short such that the central bit period T_{b} is constant in time.

The central bit period T_{b} and the deviation ΔT_{b} are determined for every time slice or rather time sub-range by minimizing the following cost functional K:

$$\begin{matrix}K = {\sum }_{i = 0}^{N - 1} [ \frac{{t}_{edge} ( i )}{{T}_{a}} - {k}_{i , η} \cdot \frac{{\hat{T}}_{b} ( η )}{{T}_{a}} - \frac{Δ {\hat{T}}_{b} ( η )}{{T}_{a}} - \\ {\sum }_{{L}_{{ISI}_{pre}}}^{{L}_{{ISI}_{post}}} {\hat{h}}_{r , f} ( {k}_{i} - ξ , b ( {k}_{i} ) , b ( {k}_{i} - 1 ) , b ( {k}_{i} - ξ ) , b ( {k}_{i} - ξ - 1 ) ) - \\ {{\sum }_{μ = 0}^{{M}_{PJ} - 1} {\hat{C}}_{μ} \cdot sin ( 2 π \cdot {\hat{v}}_{μ} / {T}_{a} \cdot {k}_{i} + {\hat{Ψ}}_{μ} ) ]}^{2} ,\end{matrix} \qquad ( E \text{.7} )$$

which is the same cost functional as the one in equation (E.6).

Based on the determined bit period \hat{T}_{b}/Tₐ and based on the determined deviation Δ\hat{T}_{b}/Tₐ, the time interval error TIE(i)/Tₐ is determined as

TIE(i)/Tₐ=t_{edge}(i)/Tₐ−k_{i,η}·\hat{T}_{b}(η)/Tₐ−Δ\hat{T}_{b}(η)/Tₐ.

Put another way, the time interval error TIE(i)/Tₐ corresponds to the first three terms in equations (E.6) and (E.7), respectively.

However, one or more of the jitter components may also be incorporated into the definition of the time interval error TIE(i)/Tₐ.

In the equation above regarding the time interval error TIE(i)/Tₐ, the term k_{i,η}·\hat{T}_{b}(η)/Tₐ+Δ\hat{T}_{b} (η)/Tₐ represents the clock signal for the i-th signal edge. This relation can be rewritten as follows \hat{T}_{clk}=k_{i,η}·\hat{T}_{b}(η)/Tₐ+Δ\hat{T}_{b} (η)/Tₐ.

As already described, a least mean squares approach is applied with which at least the constant central bit period T_{b} and the deviation ΔT_{b} from the central bit period T_{b} are determined.

In other words, the time interval error TIE(i)/Tₐ is determined and the clock signal T_{clk} is recovered by the analysis described above.

In some embodiments, the total time interval error TIE_{TJ}(k) is determined employing the clock data recovery method described above (step S.3.1 in FIG. 3).

Generally, the precision or rather accuracy is improved since the occurring perturbations are considered when determining the bit period by determining the times t_{edge}(i) of signal edges based on the received input signal and by then minimizing the cost functional K.

Decoding the Input Signal

With the recovered clock signal T_{clk} determined by the clock recovery analysis described above, the input signal is divided into the individual symbol intervals and the values of the individual symbols (“bits”) b(k) are determined.

The signal edges are assigned to respective symbol intervals due to their times, namely the times t_{edge}(i) of signal edges. Usually, only one signal edge appears per symbol interval.

In other words, the input signal is decoded by the analysis module 20, thereby generating a decoded input signal. Thus, b(k) represents the decoded input signal.

The step of decoding the input signal may be skipped if the input signal comprises an already known bit sequence. For example, the input signal may be a standardized signal such as a test signal that is determined by a communication protocol. In this case, the input signal does not need to be decoded, as the bit sequence contained in the input signal is already known.

Joint Analysis of the Step Response and of the Periodic Signal Components

The analysis module 20 is configured to jointly determine the step response of the signal source 24 and the transmission channel 26 on one hand and the vertical periodic noise parameters defined in equation (E.5) on the other hand, wherein the vertical periodic noise parameters are the amplitudes Aᵢ, the frequencies ƒᵢ and the phases ϕᵢ (step S.3.2 in FIG. 3).

Therein and in the following, the term “determine” is understood to mean that the corresponding quantity may be computed and/or estimated with a predefined accuracy.

Thus, the term “jointly determined” also encompasses the meaning that the respective quantities are jointly estimated with a predefined accuracy.

However, the vertical periodic jitter parameters may also be jointly determined with the step response of the signal source 24 and the transmission channel 26 in a similar manner.

The concept is generally called joint analysis method.

In general, the precision or rather accuracy is improved due to jointly determining the step response and the periodic signal components.

Put differently, the first three terms in equation (E.5), namely

$${\sum }_{k = - {N}_{pre}}^{{N}_{post}} [ b ( k ) - b ( k - 1 ) ] \cdot {h}_{s} ( t / {T}_{b} - k , b ( k ) ) + {x}_{- ∞} + {\sum }_{i = 0}^{{N}_{PN ( v )} - 1} {A}_{i} \cdot sin ( 2 π \cdot {f}_{i} / {f}_{b} \cdot t / {T}_{b} + {ϕ}_{i} ) ,$$

are jointly determined by the analysis module 20.

As a first step, the amplitudes Aᵢ, the frequencies ƒᵢ and the phases ϕᵢ are roughly estimated via the steps depicted in FIG. 4.

First, a clock data recovery is performed based on the received input signal (step S.4.1), for example as described above.

Second, the input signal is decoded (step S.4.2).

Then, the step response, for example the one of the signal source 24 and the transmission channel 26, is roughly estimated based on the decoded input signal (step S.4.3), for example by matching the first term in equation (E.5) to the measured input signal, for example via a least mean squares approach.

Therein and in the following, the term “roughly estimated” is to be understood to mean that the corresponding quantity is estimated with an accuracy being lower compared to the case if the quantity is determined.

Now, a data dependent jitter signal x_{DDJ} being a component of the input signal only comprising data dependent jitter is reconstructed based on the roughly estimated step response (step S.4.4).

The data dependent jitter signal x_{DDJ} is subtracted from the input signal (step S.4.5). The result of the subtraction is the signal x_{PN+RN} that approximately only contains periodic noise and random noise.

Finally, the periodic noise parameters Aᵢ, ƒᵢ, ϕᵢ are roughly estimated based on the signal x_{PN+RN} (step S.4.6), for example via a fast Fourier transform of the signal x_{PN+RN}.

In the following, these roughly estimated parameters are marked by subscripts “0”, i.e. the rough estimates of the frequencies are ƒ_{i,0} and the rough estimates of the phases are ϕ_{i,0}. The roughly estimated frequencies ƒ_{i,0} and phases ϕ_{i,0} correspond to working points for linearizing purposes as shown hereinafter.

Accordingly, the frequencies and phases can be rewritten as follows:

ƒᵢ/ƒ_{b}=ƒ_{i,0}/ƒ_{b}+Δƒᵢ/ƒ_{b}

ϕᵢ=ϕ_{i,0}+Δϕᵢ (E.8)

Therein, Δƒᵢ and Δ_{ϕi} are deviations of the roughly estimated frequencies ƒ_{i,0} and phases ϕ_{i,0} from the actual frequencies and phases, respectively. By construction, the deviations Δƒᵢ and Δ_{ϕi} are much smaller than the associated frequencies ƒᵢ and phases ϕᵢ, respectively.

With the re-parameterization above, the sine-function in the third term in equation (E.5), namely

$${\sum }_{i = 0}^{{N}_{PN ( v )} - 1} {A}_{i} \cdot sin ( 2 π \cdot {f}_{i} / {f}_{b} \cdot t / {T}_{b} + {ϕ}_{i} ) ,$$

can be linearized as follows while using small-angle approximation or rather the Taylor series

$${A}_{i} \cdot sin ( 2 π \cdot {f}_{i} / {f}_{b} \cdot t / {T}_{b} + {ϕ}_{i} ) = {A}_{i} \cdot sin ( 2 π \cdot {f}_{i , 0} / {f}_{b} \cdot t / {T}_{b} + {ϕ}_{i , 0} + 2 π \cdot Δ {f}_{i} / {f}_{b} \cdot t / {T}_{b} + {Δϕ}_{i} ) = {A}_{i} \cdot [ sin ( 2 π \cdot {f}_{i , 0} / {f}_{b} \cdot t / {T}_{b} + {ϕ}_{i , 0} ) \cdot cos ( 2 π \cdot Δ {f}_{i} / {f}_{b} \cdot t / {T}_{b} + {Δϕ}_{i} ) + cos ( 2 π \cdot {f}_{i , 0} / {f}_{b} \cdot t / {T}_{b} + {ϕ}_{i , 0} ) \cdot sin ( 2 π \cdot Δ {f}_{i} / {f}_{b} \cdot t / {T}_{b} + {Δϕ}_{i} ) ] \approx {A}_{i} \cdot sin ( 2 π \cdot {f}_{i , 0} / {f}_{b} \cdot t / {T}_{b} + {ϕ}_{i , 0} ) + {A}_{i} \cdot cos ( 2 π \cdot {f}_{i , 0} / {f}_{b} \cdot t / {T}_{b} + {ϕ}_{i , 0} ) \cdot [ 2 π \cdot Δ {f}_{i} / {f}_{b} \cdot t / {T}_{b} + {Δϕ}_{i} ] = {p}_{i , 0} \cdot sin ( 2 π \cdot {f}_{i , 0} / {f}_{b} \cdot t / {T}_{b} + {ϕ}_{i , 0} ) + {p}_{i , 1} \cdot 2 π \cdot t / {T}_{b} \cdot cos ( 2 π \cdot {f}_{i , 0} / {f}_{b} \cdot t / {T}_{b} + {ϕ}_{i , 0} ) + {p}_{i , 2} \cdot cos ( 2 π \cdot {f}_{i , 0} / {f}_{b} \cdot t / {T}_{b} + {ϕ}_{i , 0} ) . \qquad ( E \text{.9} )$$

In the last two lines of equation (E.9), the following new, linearly independent parameters have been introduced, which are determined afterwards:

p_{i,0}=Aᵢ

p_{i,1}=Aᵢ·Δƒᵢ/ƒ_{b}

p_{i,2}=Aᵢ·Δ_{ϕi} (E.10)

With the mathematical substitute model of equation (E.5) adapted that way, the analysis module 20 can now determine the step response hₛ(t/T_{b},b(k)), more precisely the step response hₛ^{(r)}(t/T_{b}) for rising signal edges and the step response hₛ^{(ƒ)}(t/T_{b}) for falling signal edges, and the vertical periodic noise parameters, namely the amplitudes Aᵢ, the frequencies ƒᵢ and the phases ϕᵢ, jointly, i.e. at the same time.

This may be achieved by minimizing a corresponding cost functional K, for example by applying a least mean squares method to the cost functional K. The cost functional has the following general form:

K=[A(k)·\hat{x}−x_{L}(k)]^{T}·[A(k)·\hat{x}−x_{L}(k)]. (E.11)

Therein, x_{L}(k) is a vector containing L measurement points of the measured input signal. \hat{x} is a corresponding vector of the input signal that is modelled as in the first three terms of equation (E.5) and that is to be determined. A(k) is a matrix depending on the parameters that are to be determined.

In some embodiments, matrix A(k) comprises weighting factors for the parameters to be determined that are assigned to the vector x_{L}(k).

Accordingly, the vector x_{L}(k) may be assigned to the step response hₛ^{(r)}(t/T_{b}) for rising signal edges, the step response hₛ^{(ƒ)}(t/T_{b}) for falling signal edges as well as the vertical periodic noise parameters, namely the amplitudes Aᵢ, the frequencies ƒᵢ and the phases ϕᵢ.

The least squares approach explained above can be extended to a so-called maximum-likelihood approach. In this case, the maximum-likelihood estimator \hat{x}_{L} is given by

\hat{x}_{ML}=[A^{T}(k)·Rₙ⁻¹(k)·A(k)]⁻¹·[A^{T}(k)·Rₙ⁻¹(k)·x_{L}(k)]. (E.11a)

Therein, Rₙ(k) is the covariance matrix of the perturbations, i.e. the jitter and noise components comprised in equation (E.5).

Note that for the case of pure additive white Gaussian noise, the maximum-likelihood approach is equivalent to the least squares approach.

The maximum-likelihood approach may be simplified by assuming that the perturbations are not correlated with each other. In this case, the maximum-likelihood estimator becomes

\hat{x}_{ML}≈[A^{T}(k)·((r_{n,i}(k)·1^{T})∘A(k))]⁻¹·[A^{T}(k)·(r_{n,i}(k)∘x_{L}(k))]. (E.11b)

Therein, 1^{T} is a unit vector and the vector r_{n,i}(k) comprises the inverse variances of the perturbations.

For the case that only vertical random noise and horizontal random noise are considered as perturbations, this becomes

$${[ {\underline{r}}_{n , i} ( k ) ]}_{l} = {( \frac{{σ}_{ϵ , RJ}^{2}}{{{T}_{b}}^{2}} {\sum }_{m = - {N}_{post}}^{{N}_{pre}} {[ b ( k - l - m ) - b ( k - l - m - 1 ) ]}^{2} \cdot {( h ( m , b ( m ) ) )}^{2} + {σ}_{RN ( v )}^{2} )}^{- 1} \qquad ( E \text{.11} c )$$

Employing equation (E.11c) in equation (E.11b), an approximate maximum likelihood estimator is obtained for the case of vertical random noise and horizontal random noise being approximately Gaussian distributed.

If the input signal is established as a clock signal, i.e. if the value of the individual symbol periodically alternates between two values with one certain period, the approaches described above need to be adapted. The reason for this is that the steps responses usually extend over several bits and therefore cannot be fully observed in the case of a clock signal. In this case, the quantities above have to be adapted in the following way:

$$\hat{\underline{x}} = {[ {( {\hat{\underline{h}}}_{s}^{( r )} )}^{T} {( {\hat{\underline{h}}}_{s}^{( f )} )}^{T} {\hat{\underline{p}}}_{3 {N}_{Pj}}^{T} ]}^{T} \qquad ( E \text{.11} d )$$

$$\underline{\underline{A}} ( k ) = [ {\underline{\underline{b}}}_{L , N}^{( r )} ( k ) - {\underline{\underline{b}}}_{L , N}^{( r )} ( k - {T}_{b} / {T}_{a} ) {\underline{\underline{b}}}_{L , N}^{( f )} ( k ) - {\underline{\underline{b}}}_{L , N}^{( f )} ( k - {T}_{b} / {T}_{a} ) {\underline{\underline{t}}}_{L , 3 {N}_{PJ}} ( k ) ]$$

$${\underline{x}}_{L} ( k ) = [ {\underline{\underline{b}}}_{L , N}^{( r )} ( k ) - {\underline{\underline{b}}}_{L , N}^{( r )} ( k - {T}_{b} / {T}_{a} ) ] \cdot {\underline{h}}_{s}^{( r )} + [ {\underline{\underline{b}}}_{L , N}^{( f )} ( k ) - {\underline{\underline{b}}}_{L , N}^{( f )} ( k - {T}_{b} / {T}_{a} ) ] \cdot {\underline{h}}_{s}^{( f )} + {\underline{\underline{t}}}_{L , 3 {N}_{PJ}} ( k ) \cdot {\underline{p}}_{3 {N}_{Pj}} + {\underline{n}}_{L} ( k ) .$$

Variation Parameter(s) Associated with the Determined Step Response

At least one variation parameter associated with the determined step response hₛ(t/T_{b},b(k)) is determined.

In general, the variation parameter is indicative of a reliability of the determined step response hₛ(t/T_{b},b(k)).

The at least one variation parameter comprises additional information on the variation of the determined step response hₛ(t/T_{b},b(k)), more precisely on the variation of samples associated with the determined step response hₛ(t/T_{b},b(k)).

With a slight adaptation of notation, estimated values of the step response ĥₛᵣ, of the initial signal value ŷ_{∞}, and of the periodic components p can be written as

$$\hat{x} = [ \begin{matrix}{\hat{h}}_{sr} \\ {\hat{y}}_{∞} \\ \hat{p}\end{matrix} ] = {A}^{+} \tilde{y} \qquad ( E \text{.12} )$$

Therein, A⁺ is the pseudo-inverse of the system matrix, which may also be called observation matrix, and \tilde{y} represents the vector of the measured input signal samples.

In order to determine the at least one variation parameter, the variance Pₓₓ of the estimate \hat{x} is determined as follows:

$${P}_{xx} = E \{ Δ x \cdot Δ {x}^{T} \} = E \{ ( \hat{x} - x ) \cdot {( \hat{x} - x )}^{T} \} = E \{ ( {A}^{+} \tilde{y} - {A}^{+} y ) {( {A}^{+} \tilde{y} - {A}^{+} y )}^{T} \} = {A}^{+} \cdot E \{ ( \tilde{y} - y ) {( \tilde{y} - y )}^{T} \} \cdot {A}^{T} = {A}^{+} \cdot E \{ Δ y \cdot Δ {y}^{T} \} \cdot {A}^{T} = {A}^{+} \cdot {P}_{yy} \cdot {A}^{+ T} \qquad ( E \text{.13} )$$

The covariance matrix P_{yy} of the input signal samples still has to be determined.

The covariance matrix P_{yy} may be simplified by applying at least one of the following approximations.

The individual input signal samples may be assumed to each have the same variance σ_{yy}². Thus, the overall number of variation parameters to be determined is reduced, as the respective variation parameter for each sample associated with the step response is the same.

The individual samples associated with the step response may be assumed to be uncorrelated. Thus, the covariance matrix becomes a diagonal matrix, as all off-diagonal elements describing the cross-correlations are zero.

With these approximations, the covariance matrix P_{yy} becomes diagonal and equation (E.13) is simplified as follows:

Pₓₓ=A⁺·A^{T}·σ_{yy}² (E.14)

The value of the variance σ_{yy}² has to be determined. However, a rough estimate of the variance σ_{yy}² may be sufficient in order to assess the reliability of the determined step response.

In other words, a precise calculation of the variance σ_{yy}² may not be necessary.

The matrix Pₓₓ comprises information on respective variances of the step response ĥₛᵣ, the initial signal value ŷ_{∞} and of the periodic components \hat{p}, namely

$${P}_{xx} = ( \begin{matrix}{P}_{hh} & {P}_{hy} & {P}_{hp} \\ {P}_{yh} & {P}_{yy} & {P}_{yp} \\ {P}_{ph} & {P}_{py} & {P}_{pp}\end{matrix} ) \qquad ( E \text{.15} )$$

The variances of the individual samples associated with the step response ĥₛᵣ correspond to the main diagonal of the submatrix Pₕₕ, i.e. to diag(Pₕₕ).

The standard deviations of the individual samples associated with the step response ĥₛᵣ thus correspond to the square roots of the individual diagonal elements, i.e. to \sqrt{diag(Pₕₕ)}.

Based on the standard deviation, a corresponding confidence interval can be determined for the determined step response in the usual manner. For example, the confidence interval may correspond to a 36 interval, i.e. to three standard deviations. The confidence interval represents an interval in which the true value of the step response or rather the true values of the respective samples associated with the step response lie with a probability of 95%.

It is noted that alternatively or additionally to the variance, the standard deviation and the confidence interval, a range and/or a span associated with the step response may be determined.

The range corresponds to the difference of the maximum value and the minimum value of the respective sample(s) associated with the step response.

The span corresponds to the difference between the 95^{th} percentile and the 5^{th} percentile of the respective sample(s) associated with the step response. Thus, the span is less susceptible to extreme outliers compared to the range.

Thus, the at least one variation parameter may comprise a confidence interval, a variance, a standard deviation, a range, and/or a span.

A respective graphic representation of the at least one determined variation parameter and of the determined step response may be generated and displayed on the display 22.

In some embodiments, the graphic representation associated with the determined step response and the graphic representation associated with the at least one determined variation parameter are visualized on the display 22 simultaneously.

In general, the graphic representations may each comprise a diagram, a text message, an icon, a two-dimensional plot, a three-dimensional plot, and/or a heat map.

Additionally or alternatively, the graphic representations may comprise predefined colorings corresponding to predefined quantities, such that the different quantities are easily distinguishable.

For example, a different color may be associated with the determined step response compared to the at least one determined variation parameter.

A particular example of the graphic representations displayed on the display 22 is illustrated in FIG. 5. In this example, the step response is visualized as a diagram, wherein the determined step response is plotted against time.

The at least one variation parameter is visualized as an area 28 around the plot of the determined step response. The area 28 is confined by an upper threshold function ƒᵤ and a lower threshold function ƒₗ indicating the confidence interval with respect to the determined step response.

Optionally, the graphic representation of the at least one variation parameter may comprise a user warning 30 if a value of the at least one variation parameter is greater than a predetermined threshold.

In general, the user warning 30 may be configured such that the user attention is immediately drawn to the user warning. For example, the user warning 30 comprises at least one of a coloring, a text message, or a warning sign.

The user warning 30 may be displayed as an overlay to the graphic representation of the at least one variation parameter and/or the graphic representation of the determined step response.

Alternatively or additionally, the user warning 30 may have a distinctively different coloring than the graphic representation of the at least one variation parameter and/or the graphic representation of the determined step response.

A large value of the at least one variation parameter may indicate that the determined step response is not particularly reliable, as the determined values of the samples (each) have a large variation.

In other words, the user is automatically warned by the user warning 30 if the variation of the determined step response is larger than the predetermined threshold, which is an indication of a potentially not reliable result for the step response.

Thus, additional information on the determined step response, namely the at least one variation parameter, is provided and visualized on the display 22. This additional information can help a user in assessing the reliability of the determined step response.

For example, if the at least one variation parameter indicates a large variation of the samples associated with the determined step response, it may be concluded that there is an error and/or perturbation in the measurement setup that prevents a precise calculation of the step response.

If, on the other hand, the at least one variation parameter indicates a small variation of the samples associated with the determined step response, it may be concluded that the determined step response is trustworthy.

Thus, the at least one variation parameter provides an easy to understand measure for the reliability of the determined step response. Accordingly, even inexperienced users can assess whether the determined step response is correct without knowledge of the supposed shape of the step response.

Determination of Jitter Components

Based on the determined step response, one or several jitter and/or noise components of the input signal may be determined. Various techniques for this determination are described in detail in US patent application US 2020 0 235 829 A1, which is hereby incorporated in its entirety by reference.

Certain embodiments disclosed herein, for example the respective module(s), utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be use synonymously with the term “signals” in this paragraph. It will be further appreciated that the terms “circuitry,” “circuit,” “one or more circuits,” etc., can be used synonymously herein.

In an embodiment, circuitry includes, among other things, one or more computing devices such as a processor (e.g., a microprocessor), a central processing unit (CPU), a digital signal processor (DSP), an application-specific integrated circuit (ASIC), a field-programmable gate array (FPGA), a system on a chip (SoC), or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes one or more processors or portions thereof and accompanying software, firmware, hardware, and the like.

In an embodiment, the analysis module 20 includes one or more circuits configured to carry out one or more steps of the methods of Claims 1-15. In an embodiment, the analysis module includes a special purpose computer or computer circuits configured to carry out one or more steps of the methods of Claims 1-15. In an embodiment, the analysis module includes a computer program product or computer readable media having executable instructions stored thereon, which when executed by one or more computing devices, processors, or computer circuits, causes the one or more circuits to carry out one or more steps of the methods of Claims 1-15.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

1. A jitter determination method for determining at least one jitter component of an input signal, wherein the input signal is generated by a signal source, the jitter determination method comprising:
receiving the input signal;
determining a step response based on the input signal, the step response being associated with at least the signal source; and
determining at least one variation parameter associated with the determined step response, wherein the at least one variation parameter is indicative of a reliability of the determined step response.

2. The jitter determination method of claim 1, wherein the at least one variation parameter comprises at least one of a confidence interval, a standard deviation, a variance, a range, or a span.

3. The jitter determination method of claim 1, wherein the step response is determined by a least squares technique.

4. The jitter determination method of claim 1, wherein a covariance matrix or a covariance submatrix associated with the step response is determined at least partially, and wherein the at least one variation parameter is determined based on the determined covariance matrix or the determined covariance submatrix.

5. The jitter determination method of claim 4, wherein the at least one variation parameter is determined based on a diagonal of the determined covariance matrix or a diagonal of the determined covariance submatrix.

6. The jitter determination method of claim 1, wherein the step response and at least one periodic perturbation component of the input signal are determined jointly.

7. The jitter determination method of claim 6, wherein the at least one periodic perturbation component is a vertical periodic perturbation component.

8. The jitter determination method of claim 6, wherein a rough estimate of the at least one periodic perturbation component is determined, and wherein the step response and the at least one periodic perturbation component of the input signal are determined jointly based on the rough estimate of the at least one periodic perturbation component.

9. The jitter determination method of claim 1, wherein a graphic representation of the at least one variation parameter is determined.

10. The jitter determination method of claim 9, wherein the graphic representation is visualized on a display.

11. The jitter determination method of claim 10, wherein the graphic representation of the at least one variation parameter is visualized together with a graphic representation of the determined step response.

12. The jitter determination method of claim 9, wherein the graphic representation comprises a user warning if a value of the at least one variation parameter is greater than a predetermined threshold.

13. The jitter determination method of claim 12, wherein the user warning comprises at least one of a coloring, a text message, or a warning sign.

14. The jitter determination method of claim 1, wherein the input signal is pulse amplitude modulation (PAM)-N coded, wherein N is an integer greater than 1.

15. The jitter determination method of claim 1, wherein at least one jitter component of the input signal is determined based on the determined step response.

16. A measurement instrument, comprising at least one input channel and an analysis circuit being connected to the at least one input channel,
wherein the measurement instrument is configured to receive an input signal via the at least one input channel and to forward the received input signal to the analysis circuit;
wherein the analysis circuit is configured to determine a step response based on the received input signal, wherein the step response is associated with at least a signal source generating the input signal; and
wherein the analysis circuit further is configured to determine at least one variation parameter associated with the determined step response, wherein the at least one variation parameter is indicative of a reliability of the determined step response.

17. The measurement instrument of claim 16, wherein the at least one variation parameter comprises at least one of a confidence interval, a standard deviation, a variance, a range, or a span.

18. The measurement instrument of claim 16, further comprising a display, wherein the measurement instrument is configured to visualize the at least one determined variation parameter on the display.

19. The measurement instrument of claim 18, wherein the measurement instrument is configured to visualize the at least one determined variation parameter and the determined step response on the display simultaneously.

20. The measurement instrument of claim 16, wherein the measurement instrument is an oscilloscope.
